(19) United States
(12) Patent Application Publication
(10) Pub. No.: US 2025/0386513 A1
(43) Pub. Date: Dec. 18, 2025

(54) FERROELECTRIC FIELD EFFECT TRANSISTOR, INVERTED FLASH AND MANUFACTURING METHOD OF FERROELECTRIC FIELD EFFECT

(71) Applicant: Taiwan Semiconductor Manufacturing Company, Ltd., Hsinchu (TW)

(72) Inventors: Georgios Vellianitis, Heverlee (BE); Marcus Johannes Henricus Van Dal, Linden (BE); Gerben DOORNBOS, Kessel-Lo (BE)

(73) Assignee: Taiwan Semiconductor Manufacturing Company, Ltd., Hsinchu (TW)

(21) Appl. No.: 18/745,758

(22) Filed: Jun. 17, 2024

(51) Int. Cl. H10B 51/30; H10B 41/27; H10B 41/30; H10B 51/20

(52) U.S. Cl. CPC H10B 51/30; H10B 41/27; H10B 41/30; H10B 51/20

(57) ABSTRACT

A ferroelectric field effect transistor (FET), an inverted Flash and a manufacturing method thereof are provided. The ferroelectric FET includes a channel layer, a ferroelectric layer and more than one metal gates. The ferroelectric layer is disposed on the channel layer. The more than one metal gates are disposed on the ferroelectric layer. The metal gates have different work functions, so that more than one coercive fields are controlled according to the metal gates.

### BACKGROUND

The disclosure relates in general to a semiconductor device and a manufacturing method thereof, and more particularly to a ferroelectric field effect transistor (FET), an inverted Flash and a manufacturing method of the ferroelectric FET.

Along the development of the semiconductor technology, memory elements become more attractive when multi-bit operation is enabled. For obtaining the area benefits, 3D integration is required. Moreover, multi bits memory cell based on ferroelectrics requires a lot of area and complicated process integration. In conventional, multi bits could not be realized in one device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a ferroelectric field effect transistor (FET) according to one embodiment of the present disclosure.

FIG. 2 shows a Polarization-Voltage (PV) loop of the ferroelectric FET according to one embodiment of the present disclosure.

FIG. 3 shows an inverted Flash according to one embodiment of the present disclosure.

FIGS. 4A to 4H illustrate a manufacturing method of the ferroelectric FET according to one embodiment of the present disclosure.

FIG. 5 illustrates a manufacturing method of the ferroelectric FET for 3D integration.

FIG. 6 shows a ferroelectric FET according to another embodiment of the present disclosure.

FIGS. 7A to 7E illustrate a manufacturing method of the inverted Flash according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

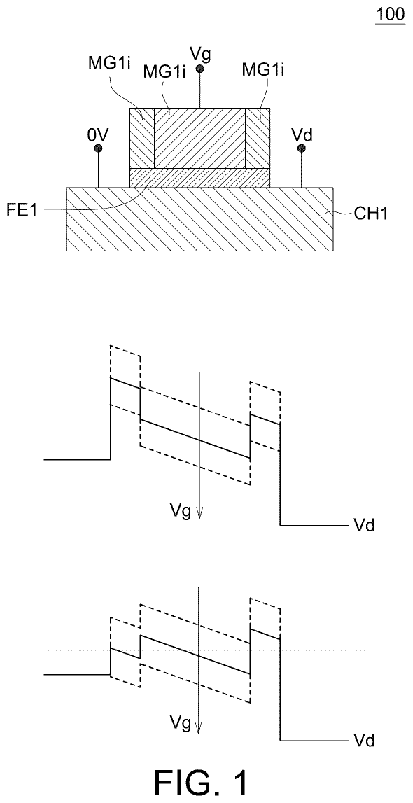

Please refer to FIG. 1, which shows a ferroelectric field effect transistor (FET) 100 according to one embodiment of the present disclosure. The ferroelectric FET 100 includes a channel layer CH1, a ferroelectric layer FE1 and more than one metal gates MG1i. The ferroelectric layer FEL is disposed on the channel layer CH1. The ferroelectric layer FE1 may include multiple stacks of ferroelectric and dielectric layers, such as dielectric/ferroelectric/dielectric, ferroelectric/dielectric or combination thereof. Typical examples are HfZrO/SiO2. In some embodiment, the dielectric size is ranged from 0.1 nm to up to 3 nm. The metal gates MG1i are disposed on the ferroelectric layer FE1. In one embodiment, the metal gates MG1i are formed by blanket deposition. The FIG. 1, the quantity of the metal gates MG1i is, for example, 3. In another embodiment, the quantity of the metal gates MG1i may be 2, 4, 5 or more than 5. In the present embodiment, the metal gates MG1i have different work functions, so that more than one coercive fields are controlled according to the metal gates MG1i.

As shown in the FIG. 1, when a gate voltage Vg is applied on the metal gates MG1i and the drain voltage Vd is applied on the channel layer CH1, different parts of the channel layer CH1 could be controlled to be corresponding different threshold voltages. The multi threshold voltages ends up multi bits operation. As such, multi bits operation could be enabled in the ferroelectric FET 100. In the FIG. 1, the left metal gate MG1i and the right metal gate MG1i should have the same material to obtain the graph in middle; and the three metal gates MG1 have different materials to obtain the bottom graph.

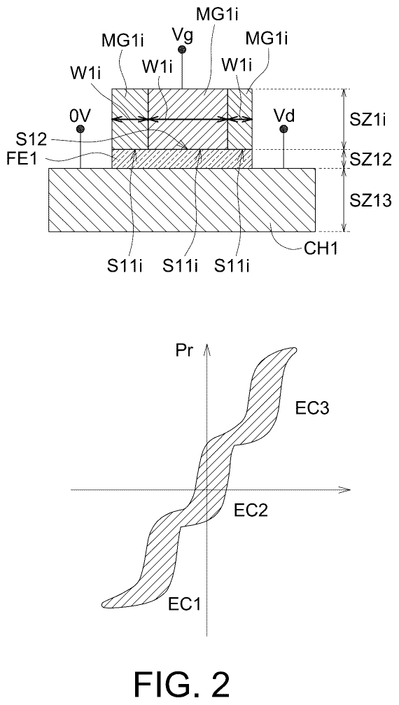

Please refer to FIG. 2, which shows a Polarization-Voltage (PV) loop of the ferroelectric FET 100 according to one embodiment of the present disclosure. The metal gates MG1i having different work functions would result multiple coercive fields EC1, EC2, EC3. The coercive fields EC1, EC2, EC3 could be controlled by the ferroelectric layer FE1, the sizes of the metal gates MG1i and the work functions of the metal gates MG1i.

In one embodiment, the metal gates MG1i have different materials for different work functions. For example, the work functions could be controlled by doping degree of dopants, or the mixing ratio of two or more materials. The work functions of the metal gates MG1i may be sequentially increased, or randomly changed. Materials of the metal gates MG1i are, for example, selected from TiN, Ti, W, Mo, Nb, TaN, Ru, Al, TiAl, Pd, Pt, Ni, poly-Si and a combination thereof.

As shown in the FIG. 2, the metal gates MG1i have different widths W1i. In another embodiment, the metal gates MG1i may have substantially identical widths W1i.

As shown in the FIG. 2, the metal gates MG1i have substantially identical sizes SZ11i. Sizes of each of the metal gates MG1i is 1 nm to 20 nm. In another embodiment, the metal gates MG1i may have different size SZ11i.

The metal gates MG1i are disposed on and directly contacted the ferroelectric layer FE1. In particular, a plurality of bottom surfaces S11i of the metal gates MG1i directly contact a top surface S12 of the ferroelectric layer FE1.

A material of the ferroelectric layer FEL is, for example, selected form HfO2, ZrO2, HfZrO with doping, HfZrO without doping, AlScN, BaTiO3, perovskite (oxides of the form ABO3 with A and B metals), and a combination thereof. And, a size SZ12 of the ferroelectric layer FEL is 5 nm to 20 nm.

A material of the channel layer CH1 is, for example, selected from Si, Ge, SiGe, IGZO, InOx, IZO, ITO, SnOx, NiO, Cu2O, and a combination thereof. And, a size SZ13 of the channel layer CH1 is 1 nm to 20 nm. As shown in FIG. 2, the channel layer CH1 is a single-layer structure. In another embodiment, the channel layer CH1 may be a bi-layers structure including two layers with different materials.

According to the embodiments described as above, the multi metal gates architecture is used in the ferroelectric FET 100, so that the ferroelectric FET 100 has the multi bits capability.

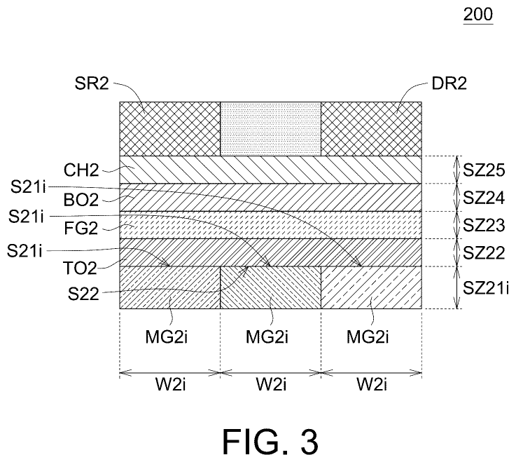

In another embodiment, the multi metal gates architecture could be used in an inverted Flash. Please refer to FIG. 3, which shows an inverted Flash 200 according to one embodiment of the present disclosure. The inverted Flash 200 includes a plurality of metal gates MG2i, a tunnel oxide layer TO2, a floating gate FG2, a block oxide layer BO2, a channel layer CH2, a source SR2 and a drain DR2. The tunnel oxide layer TO2 is disposed on the metal gates MG2i. The floating gate FG2 is disposed on the tunnel oxide layer TO2. The block oxide layer BO2 is disposed on the floating gate FG2. The channel layer CH2 is disposed on the block oxide layer BO2. The source SR2 is disposed on the channel layer CH2. In this embodiment, the metal gates MG2i have different work functions, so that more than one tunneling probabilities are obtained according to the metal gates MG2i.

In one embodiment, the metal gates MG2i have different materials for different work functions. For example, the work functions could be controlled by doping degree of dopants, or the mixing ratio of two or more materials. The FIG. 3, the quantity of the metal gates MG2i is, for example, 3. In another embodiment, the quantity of the metal gates MG2i may be 2, 4, 5 or more than 5. The work functions of the metal gates MG2i may be sequentially increased, or randomly changed. Materials of the metal gates MG2i are, for example, selected from TiN, Ti, W, Mo, Nb, TaN, Ru, Al, TiAl, Pd, Pt, Ni, poly-Si and a combination thereof.

As shown in the FIG. 3, the metal gates MG2i have substantially identical widths W2i. In another embodiment, the metal gates MG2i may have different widths W2i.

As shown in the FIG. 3, the metal gates MG3i have substantially identical sizes SZ21i. Size of each of the metal gates MG2i is 1 nm to 20 nm. In another embodiment, the metal gates MG2i may have different sizes SZ21i.

The tunnel oxide layer TO2 is disposed on the directly contacted the metal gates MG2i. In particular, a plurality of top surfaces S21i of the metal gates MG2i directly contact a bottom surface S22 of the tunnel oxide layer TO2.

A material of the tunnel oxide layer TO2 includes, for example, one or more oxide materials such as HfO2, ZrO2, BaZrO2, BaTiO3, Ta2O5, CaO, SrO, BaO, La2O3, Ce2O3, Pr2O3, Nd2O3, Pm2O3, Sm2O3, Eu2O3, Gd2O3, Tb2O3, Dy2O3, Ho2O3, Er2O3, Tm2O3, Yb2O3, and/or Lu2O3. The size SZ22 of the tunnel oxide layer TO2 is, for example, 3 nm to 10 nm.

A material of the block oxide layer BO2 is, for example, selected form SiN, SiO2, SiON, HfO2, ZrO2, HfZrO, Al2O3, TiO2, MgO, O, NbOx, a combination thereof. In one embodiment, the block oxide layer BO2 may include a plurality of layers with different materials. A size SZ24 of the block oxide layer BO2 is, for example, 5 nm to 20 nm.

The floating gate FG2 may, for example, be or comprise doped polysilicon and/or some other suitable conductive material(s). A size SZ23 of the floating gate FG2 is, for example, 2 nm to 20 nm.

A material of the channel layer CH2 is, for example, selected from Si, Ge, SiGe, IGZO, InOx, IZO, ITO, SnOx, NiO, Cu2O, and a combination thereof. And, a size SZ25 of the channel layer CH2 is 1nm to 20nm. As shown in FIG. 3, the channel layer CH2 is a single-layer structure. In another embodiment, the channel layer CH2 may be a bi-layers structure including two layers with different materials.

According to the embodiments described as above, the multi metal gates architecture is used in the inverted Flash 200, so that more than one tunneling probabilities are obtained according to the metal gates MG2i.

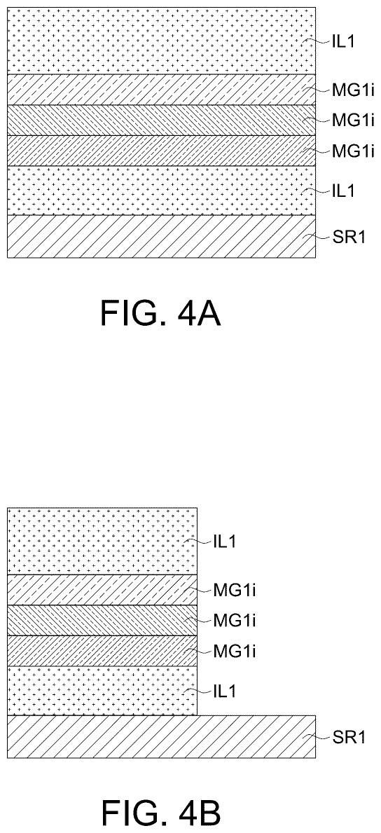

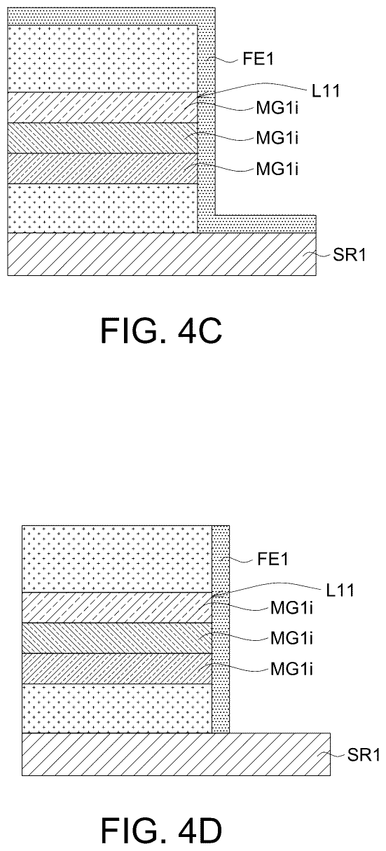

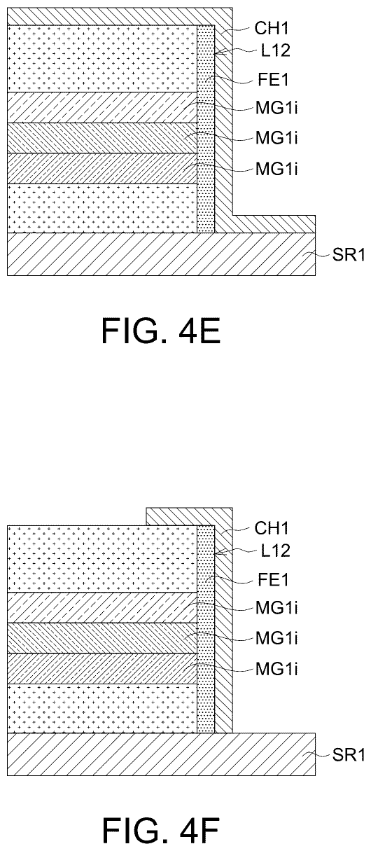

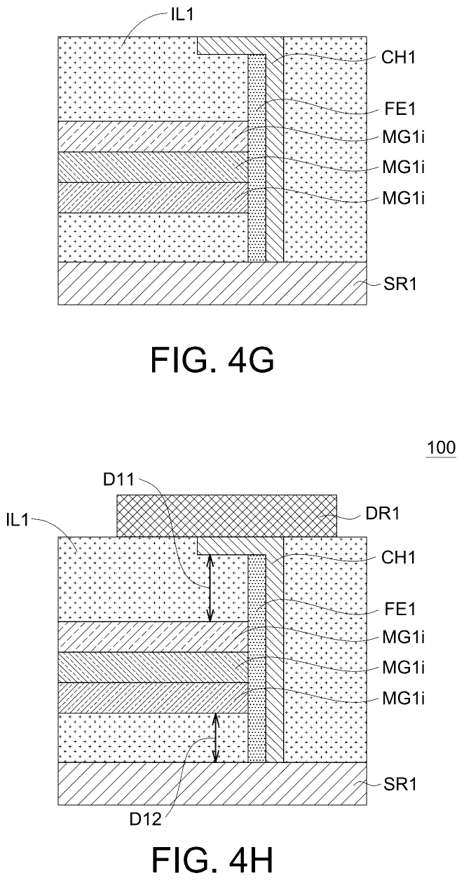

Please refer to FIGS. 4A to 4H, which illustrate a manufacturing method of the ferroelectric FET 100 according to one embodiment of the present disclosure. As shown in the FIG. 4A, a plurality of metal gates MG1i are deposed above a source SR1. The metal gates MG1i are disposed between isolation materials IL1. A quantity of the metal gates MG1i is, for example, two to five. The metal gates MG1i have different work functions. For example, the metal gates MG1i may have different materials.

Next, as shown in the FIG. 4B, the metal gates MG1i is etched to expose part of the source SR1.

Then, as shown in the FIG. 4C, a ferroelectric layer FE1 is deposited at a lateral wall L11 of the metal gates MG1i and on part of the source SR1 which is exposed. In this step, HfO2, ZrO2, HfZrO with/without doping, AlScN, are used to deposit the ferroelectric layer FE1. The size of the ferroelectric layer FEL is controlled at 1 nm to 20 nm. The ferroelectric layer FE1 may include multiple stacks of ferroelectric and dielectric layers, such as dielectric/ferroelectric/dielectric, ferroelectric/dielectric or combination thereof. Typical examples are HfZrO/SiO2. In one embodiment, the dielectric size is ranged from 0.1 nm to up to 3 nm.

Next, as shown in the FIG. 4D, part of the ferroelectric layer FE1 which is deposited on the source SR1 is etched, so that the remaining ferroelectric layer FEL is disposed at the lateral wall L11 of the metal gates MG1i. In this step, a spacer-like etching is used to etch the ferroelectric layer FE1.

Then, as shown in the FIG. 4E, a channel layer CH1 is deposited at a lateral wall L12 of the ferroelectric layer FEL and on part of the source SR1 which is exposed. In this step, Si, Ge, SiGe, IGZO, InOx, IZO, ITO, SnOx, NiO, Cu2O, or combination thereof are used to deposit the channel layer CH1. The size of the channel CHI is controlled at 1 nm to 20 nm.

Next, as shown in the FIG. 4F, part of the channel layer CHI which is deposited on the source SR1 is etched, so that the remaining channel layer CH1 is disposed at the lateral wall L12 of the ferroelectric layer FE1.

Then, as shown in the FIG. 4G, oxide is filled and the top of the oxide and the channel layer CH1 is polished through Chemical-Mechanical Planarization (CMP), for example.

Afterwards, as shown in the FIG. 4H, a drain DR1 is formed connected to the channel layer CH1. In this step, the drain DR1 is formed, for example, by metal deposition, lithography and etching. As shown in the FIG. 4H, the distance D11 between the metal gate MG1i and the channel layer CH1 is, for example, 1 nm to 10 nm, and the distance D12 between the metal gate MG1i and the source SR1 is, for example, 1 nm to 10 nm.

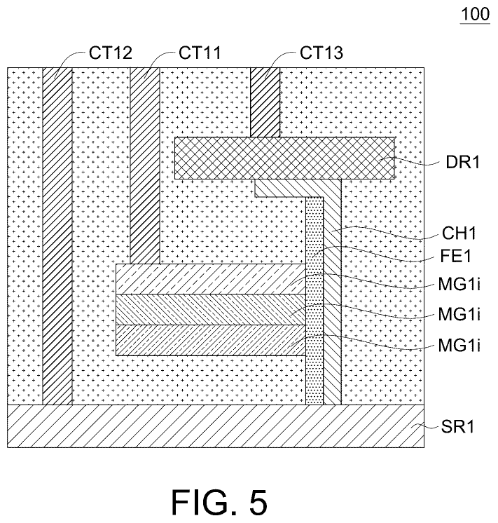

Further, please refer to FIG. 5, which illustrates a manufacturing method of the ferroelectric FET 100 for 3D integration. In this step, three contacts CT11, CT12, CT13 are formed to contact the source SR1, the metal gates MG1i and the drain DR1 respectively. As shown in the FIG. 5, the contacts CT11, CT12, CT13 are formed, for example, by staircase integration approach. In this ferroelectric FET 100, one transistor is formed.

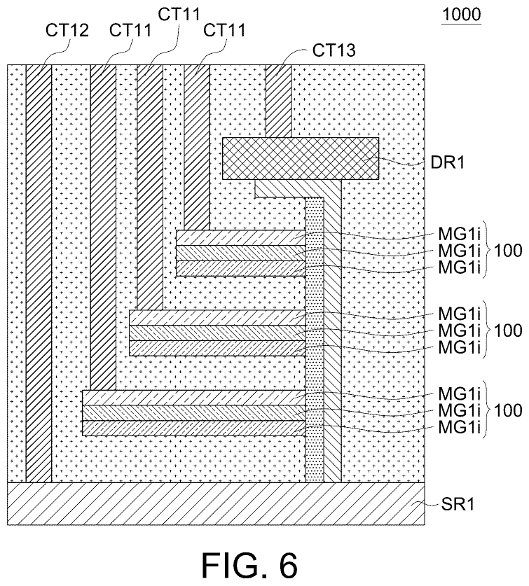

Moreover, the structure and the manufacturing method described above could be extendable to multiple stacked transistors. Please refer to FIG. 6, which shows a ferroelectric FET 1000 according to another embodiment of the present disclosure. In the FIG. 6, every transistor, i.e. the ferroelectric FET 100, could have the same metal gates MG1i with same size or different metal gates MG1i with different sizes. A plurality of contacts CT11 are used to contact the metal gates MG1i of the ferroelectric FET 100 and the contacts CT12, CT13 are used to contact the source SR1 and the drain DR1 respectively. Based above, multiple stacked transistors could be obtained.

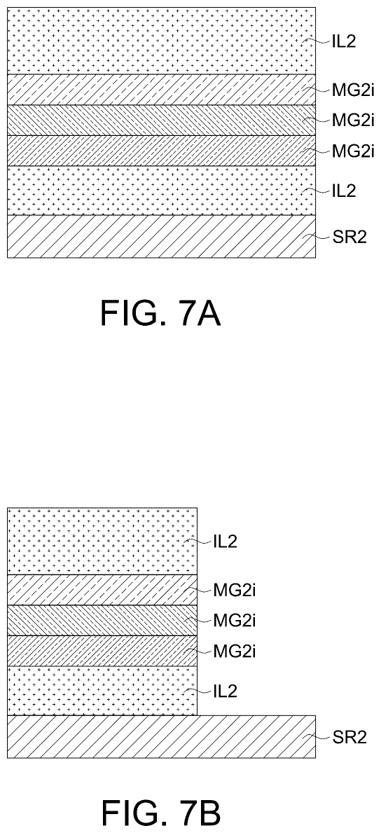

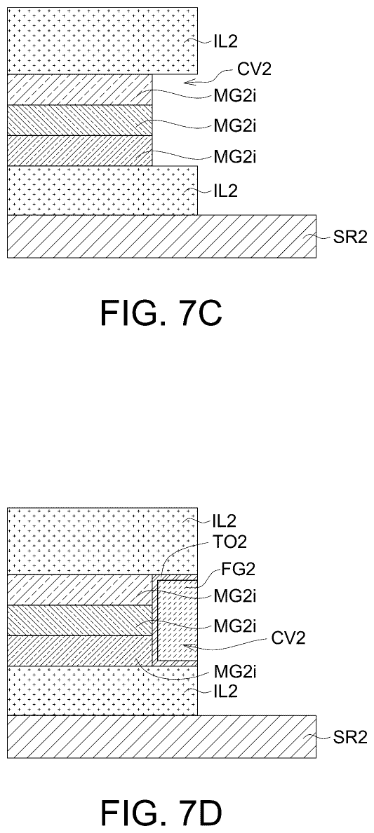

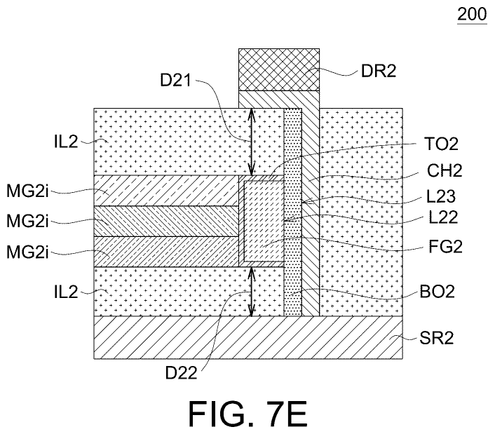

Please refer to FIGS. 7A to 7E, which illustrate a manufacturing method of the inverted Flash 200 according to one embodiment of the present disclosure. As shown in the FIG. 7A, a plurality of metal gates MG2i are deposited above a source SR2. The metal gates MG2i are disposed between isolation materials IL2. The quantity of the metal gates MG2i is, for example, two to five. The metal gates MG2i have different work functions. For example, the metal gates MG2i may have different materials.

Next, as shown in the FIG. 7B, the metal gates MG2i are etched to expose part of the source SR2.

Then, as shown in the FIG. 7C, the metal gates MG2i are laterally recessed to form a concave CV2. In this step, the metal gates MG2i are etched, but the isolation materials IL2 are nor etched or only slightly etched.

Next, as shown in the FIG. 7D, a tunnel oxide layer TO2 and a floating gate FG2 are formed in the concave CV2. In this step, the tunnel oxide layer TO2 is, for example, formed at the bottom and the side wall of the concave CV2. The floating gate FG2 is, for example, filled in the concave CV2. That is, the tunnel oxide layer TO2 covers three surfaces of the floating gate FG2, and one surface of the floating gate FG2 is exposed.

Then, as shown in the FIG. 7E, a block oxide layer BO2 is formed at a lateral surface L22 of the floating gate FG2.

Next, as shown in the FIG. 7E, a channel layer CH2 is formed at a lateral surface L23 of the block oxide layer BO2.

Afterwards, as shown in the FIG. 7E, a drain DR2 connected to the channel layer CH2 is formed. As shown in the FIG. 7E, the distance D21 between the tunnel oxide layer TO2 and the channel layer CH2 is, for example, 1 nm to 10 nm, and the distance D22 between the tunnel oxide layer TO2 and the source SR2 is, for example, 1 nm to 10 nm.

Next, contacts (not shown) could be formed to contact the source SR2, the metal gates MG2i and the drain DR2. The contacts could be formed, for example, by staircase integration approach. In this inverted Flash 200, one transistor is formed.

Moreover, the structure and the manufacturing method of the inverted Flash described above could be extendable to multiple stacked transistors through the similar manner described in the FIG. 6.

According to the embodiments described as above, multiple threshold voltages could be obtained within the same transistor. It could be used in a ferroelectric FET to obtain multiple coercive fields in a single device. Or, it could be used in an inverted Flash to obtain multiple tunneling probabilities.

Further, it is applicable to 3D architectures enabling multi bits operation within one cell. The fabrication of the 3D memory FET in which the word lines (or the bits) may have different metal layer size and materials within one device. Also, the fabrication of the 3D memory FET may have different metal layer size and materials within each of the devices in the same trench. The ferroelectric FET is controlled with the coercive fields, and the inverted Flash is controlled with the tunneling probabilities.

In one embodiment, at least the following example embodiments are disclosed.

According to one example embodiment, a ferroelectric field effect transistor (FET) is provided. The ferroelectric FET includes a channel layer, a ferroelectric layer and more than one metal gates. The ferroelectric layer is disposed on the channel layer. The more than one metal gates are disposed on the ferroelectric layer. The metal gates have different work functions, so that more than one coercive fields are controlled according to the metal gates.

Based on the ferroelectric FET described in the previous embodiments, the metal gates have different materials.

Based on the ferroelectric FET described in the previous embodiments, a quantity of the metal gates is two to five.

Based on the ferroelectric FET described in the previous embodiments, the metal gates have different widths.

Based on the ferroelectric FET described in the previous embodiments, the metal gates have substantially identical sizes.

Based on the ferroelectric FET described in the previous embodiments, a plurality of bottom surfaces of the metal gates directly contact a top surface of the ferroelectric layer.

Based on the ferroelectric FET described in the previous embodiments, materials of the metal gates are selected from TiN, Ti, W, Mo, Nb, TaN, Ru, Al, TiAl, Pd, Pt, Ni, poly-Si and a combination thereof.

Based on the ferroelectric FET described in the previous embodiments, size of each of the metal gates is 1 nm to 20 nm.

Based on the ferroelectric FET described in the previous embodiments, a material of the ferroelectric layer is selected form HfO2, ZrO2, HfZrO with doping, HfZrO without doping, AlScN, BaTiO3, perovskite, and a combination thereof.

Based on the ferroelectric FET described in the previous embodiments, a material of the channel layer is selected from Si, Ge, SiGe, IGZO, InOx, IZO, ITO, SnOx, NiO, Cu2O, and a combination thereof.

According to another example embodiment, an inverted Flash is provided. The inverted Flash includes a plurality of metal gates, a tunnel oxide layer, a floating gate, a block oxide layer, a channel layer, a source and a drain. The tunnel oxide layer is disposed on the metal gates. The floating gate is disposed on the tunnel oxide layer. The block oxide layer is disposed on the floating gate. The channel layer is disposed on the block oxide layer. The source is disposed on the channel layer. The drain is disposed on the channel layer. The metal gates have different work functions, so that more than one tunneling probabilities are obtained according to the metal gates.

Based on the inverted Flash described in the previous embodiments, the metal gates have different materials.

Based on the inverted Flash described in the previous embodiments, a quantity of the metal gates is two to five.

Based on the inverted Flash described in the previous embodiments, the metal gates have different widths.

Based on the inverted Flash described in the previous embodiments, the metal gates have substantially identical sizes.

Based on the inverted Flash described in the previous embodiments, a plurality of top surfaces of the metal gates directly contact a bottom surface of the tunnel oxide layer.

Based on the inverted Flash described in the previous embodiments, materials of the metal gates are selected from TiN, Ti, W, Mo, Nb, TaN, Ru, Al, TiAl, Pd, Pt, Ni, poly-Si and a combination thereof.

Based on the inverted Flash described in the previous embodiments, size of each of the metal gates is 1 nm to 20 nm.

According to another example embodiment, a manufacturing method of a ferroelectric field effect transistor (FET) is provided. The manufacturing method of the ferroelectric FET includes the following steps: depositing a plurality of metal gates above a source, wherein the metal gates are disposed between isolation materials; etching the metal gates to expose part of the source; depositing a ferroelectric layer at a lateral wall of the metal gates and on part of the source which is exposed; etching part of the ferroelectric layer which is deposited on the source, so that the ferroelectric layer is disposed at the lateral wall of the metal gates; depositing a channel layer at a lateral wall of the ferroelectric layer and on part of the source which is exposed; etching part of the channel layer which is deposited on the source, so that the channel layer is disposed at the lateral wall of the ferroelectric layer; and forming a drain connected to the channel layer.

Based on the manufacturing method of the ferroelectric FET described in the previous embodiments, the metal gates have different materials.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A ferroelectric field effect transistor (FET), comprising:
a channel layer;
a ferroelectric layer, disposed on the channel layer; and
more than one metal gates, disposed on the ferroelectric layer, wherein the metal gates have different work functions, so that more than one coercive fields are controlled according to the metal gates.

2. The ferroelectric FET according to claim 1, wherein the metal gates have different materials.

3. The ferroelectric FET according to claim 1, wherein a quantity of the metal gates is two to five.

4. The ferroelectric FET according to claim 1, wherein the metal gates have different widths.

5. The ferroelectric FET according to claim 1, wherein the metal gates have substantially identical sizes.

6. The ferroelectric FET according to claim 1, wherein a plurality of bottom surfaces of the metal gates directly contact a top surface of the ferroelectric layer.

7. The ferroelectric FET according to claim 1, wherein materials of the metal gates are selected from TiN, Ti, W, Mo, Nb, TaN, Ru, Al, TiAl, Pd, Pt, Ni, poly-Si and a combination thereof.

8. The ferroelectric FET according to claim 1, wherein size of each of the metal gates is 1 nm to 20 nm.

9. The ferroelectric FET according to claim 1, wherein a material of the ferroelectric layer is selected form HfO2, ZrO2, HfZrO with doping, HfZrO without doping, AlScN, BaTiO3, perovskite, and a combination thereof.

10. The ferroelectric FET according to claim 1, wherein a material of the channel layer is selected from Si, Ge, SiGe, IGZO, InOx, IZO, ITO, SnOx, NiO, Cu2O, and a combination thereof.

11. An inverted Flash, comprising:
a plurality of metal gates;
a tunnel oxide layer, disposed on the metal gates;
a floating gate, disposed on the tunnel oxide layer;
a block oxide layer, disposed on the floating gate;
a channel layer, disposed on the block oxide layer;
a source, disposed on the channel layer; and
a drain, disposed on the channel layer, wherein the metal gates have different work functions, so that more than one tunneling probabilities are obtained according to the metal gates.

12. The inverted Flash according to claim 11, wherein the metal gates have different materials.

13. The inverted Flash according to claim 11, wherein a quantity of the metal gates is two to five.

14. The inverted Flash according to claim 11, wherein the metal gates have different widths.

15. The inverted Flash according to claim 11, wherein the metal gates have substantially identical sizes.

16. The inverted Flash according to claim 11, wherein a plurality of top surfaces of the metal gates directly contact a bottom surface of the tunnel oxide layer.

17. The inverted Flash according to claim 11, wherein materials of the metal gates are selected from TiN, Ti, W, Mo, Nb, TaN, Ru, Al, TiAl, Pd, Pt, Ni, poly-Si and a combination thereof.

18. The inverted Flash according to claim 11, wherein size of each of the metal gates is 1 nm to 20 nm.

19. A manufacturing method of a ferroelectric field effect transistor (FET), comprising:
depositing a plurality of metal gates above a source, wherein the metal gates are disposed between isolation materials;
etching the metal gates to expose part of the source;
depositing a ferroelectric layer at a lateral wall of the metal gates and on part of the source which is exposed;
etching part of the ferroelectric layer which is deposited on the source, so that the ferroelectric layer is disposed at the lateral wall of the metal gates;
depositing a channel layer at a lateral wall of the ferroelectric layer and on part of the source which is exposed;
etching part of the channel layer which is deposited on the source, so that the channel layer is disposed at the lateral wall of the ferroelectric layer; and
forming a drain connected to the channel layer.

20. The manufacturing method of the ferroelectric FET according to claim 19, wherein the metal gates have different materials.
